(19) United States
(12) Patent Application Publication
(10) Pub. No.: US 2025/0059400 A1
(43) Pub. Date: Feb. 20, 2025

(54) INSULATING FILM POLISHING SOLUTION AND USAGE METHOD THEREOF

(71) Applicant: ANJI MICROELECTRONICS(SHANGHAI) CO., LTD, Shanghai (CN)

(72) Inventors: Pengyu XU, Shanghai (CN); Xingping WANG, Shanghai (CN); Yinbin CHEN, Shanghai (CN); Shangru LIU, Shanghai (CN); Changzheng JIA, Shanghai (CN); Shoutiian LI, Shanghai (CN)

(21) Appl. No.: 18/722,382

(22) PCT Filed: Dec. 23, 2022
(86) PCT No.: PCT/CN2022/141260

§ 371 Date: Jun. 20, 2024

(30) Foreign Application Priority Data
Dec. 23, 2021 (CN) 202111580690.7

(51) Int. Cl. C09G 1/02

(52) U.S. Cl. CPC C09G 1/02

(57) ABSTRACT

The present disclosure provides an insulating film polishing solution, comprising: cerium oxide, an anionic polymer, a cationic polymer, an insulating film inhibitor, and water, wherein the pattern polishing rate of the polishing rate of the insulating film polishing solution is more than 5 times that of non-pattern polishing rate. The insulation film polishing solution in the present invention has good stability and can realize an automatic stop function.

### TECHNICAL FIELD

The present disclosure relates to the field of chemical polishing, in particular to insulating film polishing solution and a using method thereof.

### BACKGROUND

With the rapid development of integrated circuits, their logical structures have become increasingly complex, and the chip surface has been designed with many high steps. It is necessary to flatten these steps while stopping layers are made of insulating oxides. Therefore, in the case where steps are present on the chip surface, the polishing rate of the polishing solution needs to be increased to polish the wafer surface. When the steps are leveled, the polishing rate of the polishing solution also decreases automatically, thereby achieving automatic polishing stop. Therefore, the field urgently needs a polishing solution that can achieve automatic polishing stop for insulating film.

### SUMMARY

A purpose of the present invention is to provide an insulating film polishing solution capable of effectively polishing patterns on the surface of a patterned wafer and capable of automatically stopping polishing at an oxide layer.

Specifically, the invention provides an insulating film polishing solution, which comprises cerium oxide, an anionic polymer, a cationic polymer, an insulating film inhibitor and water, wherein the pattern polishing rate of the insulating film polishing solution is more than 5 times that of a non-pattern polishing rate.

Preferably, the anionic polymer is selected from compounds containing carboxyl groups, sulfonic acid groups and phosphate groups.

Preferably, the polymer compounds containing carboxyl groups are polycarboxylates and/or polyamino acids:
the polymer compound containing sulfonic acid group is polybenzene sulfonic acid homopolymer or copolymer thereof:

The phosphate group is selected from one or more of phosphate, potassium phosphate, and dipotassium hydrogen triphosphate.

Preferably, the cationic polymer is a polyquaternium polymer compound and/or an imine polymer compound.

Preferably, the insulation film inhibitor is a nitrogen-containing compound.

Preferably, the insulating film inhibitor is a polyquaternium polymer and/or hydroxylamine and derivatives thereof.

Preferably, a mass percentage ratio of the anionic polymer to the cerium oxide is 0.01%-100%.

Preferably, a mass percentage ratio of the anionic polymer to the cerium oxide is 0.02%-1%.

Preferably, a mass percentage ratio of the cationic polymer to the cerium oxide is 0.01-100%.

Preferably, a mass percentage ratio of the cationic polymer to the cerium oxide is 0.01%-10%.

Preferably, a mass percentage ratio of the insulating film inhibitor to the cerium oxide is 0.01% to 100%.

Preferably, a mass percentage ratio of the insulating film inhibitor to the cerium oxide is 0.01%-10%.

Another aspect of the present invention is to provide a method of using any of the aforementioned insulating film polishing solution for polishing insulating films.

Compared with the prior art, the polishing solution disclosed by the present invention has better stability and can realize an automatic stop function.

### DETAILED DESCRIPTION

The advantages of the present invention are further explained below in conjunction with specific embodiments.

Mix cerium oxide, anionic polymer compounds with deionized water, stir thoroughly with ultrasound for 30 minutes, then add cationic polymer compounds and insulation film inhibitors to the mixture. Finally, dilute the cerium oxide content to the target content with deionized water, and adjust the polishing solution to the target pH value using a pH regulator (such as nitric acid).

The components and contents of the polishing solutions of Embodiments 1 to 9 and Comparative Embodiments 1 to 3 of the present invention are shown in Table 1. The cationic polymer compound and the insulating film inhibitor in Embodiments 4 to 8 are all polyquaternium-7, and the contents shown in Table 1 are the total contents of the two additives.

TABLE 1
Components and contents of insulating film polishing solutions
of Embodiments 1 to 9 and Comparative Embodiments 1 to 3

| | | Anionic polymer | | Cationic polymer | | insulating film | | |
|---|---|---|---|---|---|---|---|---|
| | cerium | compounds | | compounds | | inhibitor | | |
| polishing | oxide | specific | | specific | | specific | | pH |
| solution | particles | substance | content | substance | content | substance | content | value |
| Embodiment 1 | 0.2% | ammonium | 0.008% | polyquaternium-7 | 0.03% | | | 4.8 |
| | | polyacrylate | | | | | | |
| Embodiment 2 | 0.2% | ammonium | 0.008% | polyquaternium-7 | 0.005% | polyquaternium-37 | 0.025% | 4.8 |
| | | polyacrylate | | | | | | |
| Embodiment 3 | 0.2% | ammonium | 0.008% | polyquaternium-7 | 0.005% | polyquaternium-2 | 0.025% | 4.8 |
| | | polyacrylate | | | | | | |
| Embodiment 4 | 0.4% | ammonium | 0.016% | polyquaternium-7 | 0.06% | | | 4.8 |
| | | polyacrylate | | | | | | |
| Embodiment 5 | 0.1% | ammonium | 0.004% | polyquaternium-7 | 0.015% | | | 4.8 |
| | | polyacrylate | | | | | | |
| Embodiment 6 | 0.2% | ammonium | 0.008% | polyquaternium-7 | 0.035% | | | 4.8 |
| | | polyacrylate | | | | | | |
| Embodiment 7 | 0.2% | ammonium | 0.008% | polyquaternium-7 | 0.015% | | | 5.5 |
| | | polyacrylate | | | | | | |
| Embodiment 8 | 0.2% | ammonium | 0.008% | polyquaternium-7 | 0.015% | | | 4.0 |
| | | polyacrylate | | | | | | |
| Embodiment 9 | 0.2% | ammonium | 0.008% | polyquaternium-37 | 0.005% | polyquaternium-7 | 0.025% | 4.8 |
| | | polyacrylate | | | | | | |
| Embodiment 10 | 0.2% | ammonium | 0.008% | polyquaternium-37 | 0.004% | hydroxylamine | 0.04% | 4.8 |
| | | polyacrylate | | | | | | |
| Embodiment 11 | 0.2% | Dipotassium | 0.007% | polyquaternium-7 | 0.03% | | | 4.8 |
| | | hydrogen | | | | | | |
| | | phosphate | | | | | | |
| Comparative | 0.2% | ammonium | 0.106% | — | — | — | — | 4.8 |
| Embodiment 1 | | polyacrylate | | | | | | |
| Comparative | 0.2% | — | — | polyquaternium-37 | 0.003% | | | 4.8 |
| Embodiment 2 | | | | | | | | |

It should be understood that the contents of each component in Table 1 are mass percentage contents.

Further test the stability and polishing performance of the above-mentioned polishing solution. The specific testing conditions are as follows:

The TEOS blank wafer and the pattern wafer are polished by using the polishing solution prepared above respectively using the polishing apparatus and polishing conditions described above. The polishing rate was measured at 49 points at equal intervals on a diameter line from 3 mm from the wafer edge, so that the polishing rate of each polishing solution was the average of the polishing rates at 49 points. The polishing results are shown in Table 2.

TABLE 2
Polishing test results of insulating film polishing solutions of
Embodiments 1 to 9 and Comparative Embodiments 1 to 3

| | additive | | | | |
|---|---|---|---|---|---|
| | | Cationic | | | |
| | | polymer + | | | |
| | anionic | insulating film | 200 mm CMP | | |
| polishing | polymer | inhibitor | BWRR* | SHRR* | BWRR/ |
| solution | (ppm) | (ppm) | (Å/min) | (Å/min) | SHRR |
| Embodiment 1 | 8 | 300 | 163 | 3632 | 22 |
| Embodiment 2 | 8 | 300 | 94 | 1128 | 12 |
| Embodiment 3 | 8 | 300 | 11 | 56 | 5 |
| Embodiment 4 | 16 | 600 | 423 | 3900 | 9 |
| Embodiment 5 | 4 | 150 | 491 | 2552 | 5 |
| Embodiment 6 | 8 | 350 | 115 | 1676 | 15 |
| Embodiment 7 | 8 | 150 | 724 | 3384 | 5 |
| Embodiment 8 | 8 | 150 | 64 | 1276 | 20 |
| Embodiment 9 | 8 | 300 | 330 | 3408 | 10 |
| Embodiment 10 | 8 | 440 | 477 | 3164 | 6 |
| Embodiment 11 | 7 | 300 | 387 | 5216 | 13 |
| Comparative | 1060 | — | 2677 | 1237 | 0.46 |
| Embodiment 1 | | | | | |

| | | | |
|---|---|---|---|
| Comparative | — | 30 | The polishing solution |
| Embodiment 2 | | | is unstable. |

*BWRR: Blank wafer removal rate;
SHRR: Pattern wafer removal rate

Embodiments 1-9 demonstrate that by simultaneously adding anionic polymers, cationic polymers, and insulating film inhibitors, it is possible to achieve a much higher polishing rate on the convex part of the patterned wafer than on its empty wafer, with a selection ratio of 5:1 or higher.

Comparing the test results of Embodiment 6, Embodiment 7 and Embodiment 8, it can be seen that the pH value also affects the polishing properties of the polishing solution. With the increase of the pH value, the polishing rate of the polishing solution at the concave part of the pattern wafer gradually increases, indicating that the property of the polishing solution to automatically stop at the insulating film becomes weaker, but at the same time, the polishing rate at the convex part of the pattern wafer also increases. Therefore, the pH value of the polishing solution in this invention needs to be controlled within a certain range, and there is selectivity in the specific range of pH value.

Comparative Embodiment 1 shows that the polishing rate of the convex portion of the patterned wafer is much lower than that of the blank wafer after adding only anionic polymer, and is less than 50% of the blank wafer rate; however, only adding cationic polymer and insulating film inhibitor or only adding cationic polymer and insulating film inhibitor (Comparative Embodiment 2 and 3) may cause instability of the polishing solution.

The results in Table 2 indicate that the new cerium oxide polishing solution can use hydroxylamine and quaternary ammonium salt series molecules as automatic stop inhibitors. That is, when the step is low, the TEOS polishing rate of empty wafers and patterned wafers is low, and when the step is high, the convex polishing rate is high, and the concave polishing rate is low, achieving the characteristic of automatic stop.

Although the above specific embodiments of the present invention have been described in detail, they are only examples, and the present disclosure is limited to the embodiments described above. For those skilled in the art, any equivalent modification and substitution to the present invention is also covered in the present invention. Therefore, all these equivalent changes and modifications made without departing from the spirit and scope of the invention should be covered within the scope of the present invention.

1. An insulating film polishing solution, characterized in that it comprises:
cerium oxide, an anionic polymer, a cationic polymer, an insulation film inhibitor, and water;
wherein the pattern polishing rate of the polishing rate of the insulating film polishing solution is more than 5 times that of non-pattern polishing rate.

2. An insulating film polishing solution according to claim 1, characterized in that:
the anionic polymer is selected from compounds containing carboxyl groups, sulfonic acid groups and phosphate groups.

3. An insulating film polishing solution according to claim 2, characterized in that:
the polymer compounds containing carboxyl groups are polycarboxylates and/or polyamino acids;
the polymer compound containing sulfonic acid group is polybenzene sulfonic acid homopolymer or copolymer thereof;
the phosphate-containing molecule may be selected from one or more of phosphoric acid and phosphate.

4. An insulating film polishing solution according to claim 1, characterized in that:
the cationic polymer is a polyquaternium polymer compound and/or imine polymer compound.

5. An insulating film polishing solution according to claim 1, characterized in that:
the insulating film inhibitor is a nitrogen-containing compound.

6. An insulating film polishing solution according to claim 5, characterized in that:
the insulation film inhibitor is a polyquaternium polymer and/or hydroxylamine and its derivatives.

7. An insulating film polishing solution according to claim 1, characterized in that:
a mass percentage ratio of the anionic polymer to the cerium oxide is 0.01-100%.

8. An insulating film polishing solution according to claim 7, characterized in that:
a mass percentage ratio of the anionic polymer to the cerium oxide is 0.02-1%.

9. An insulating film polishing solution according to claim 1, characterized in that:
a mass percentage ratio of the cationic polymer to the cerium oxide is 0.01-100%.

10. An insulating film polishing solution according to claim 9, characterized in that:
a mass percentage ratio of the cationic polymer to the cerium oxide is 0.01-10%.

11. An insulating film polishing solution according to claim 1, characterized in that:
a mass percentage ratio of the insulation film inhibitor to the cerium oxide is 0.01%-100%.

12. An insulating film polishing solution according to claim 11, characterized in that:
a mass percentage ratio of the insulation film inhibitor to the cerium oxide is 0.01%-10%.

13. An insulating film polishing solution according to claim 1, characterized in that:
a pH value of the insulating film polishing solution ranges from 3 to 7.

14. A method of using the insulation film polishing solution as described in claim 1 for polishing an insulation film.
